(19) United States
(12) Patent Application Publication
(10) Pub. No.: US 2014/0252435 A1
(43) Pub. Date: Sep. 11, 2014

(54) SEMICONDUCTOR DEVICE

(71) Applicant: Kabushiki Kaisha Toshiba, Minato-ku (JP)

(72) Inventor: Ryota SENDA, Kanagawa-ken (JP)

(73) Assignee: KABUSHIKI KAISHA TOSHIBA, Minato-ku (JP)

(21) Appl. No.: 14/021,038

(22) Filed: Sep. 9, 2013

(30) Foreign Application Priority Data
Mar. 7, 2013 (JP) 2013-045634
May 24, 2013 (JP) 2013-109677

(51) Int. Cl. H01L 23/498

(52) U.S. Cl. CPC H01L 23/49816
USPC 257/288

(57) ABSTRACT

A semiconductor device concerning an embodiment is provided with a plate-like semiconductor substrate, electrode pads, electrode connecting conductors, and a source electrode back pad. The semiconductor substrate has a first cutout section in a first side, and has a second cutout section and a third cutout section in a second side. A drain electrode connecting conductor is provided in the first cutout section, and one end thereof touches the drain electrode pad, and the other end thereof is exposed in a back surface of the semiconductor substrate. A gate electrode connecting conductor is provided in the third cutout section, and one end thereof touches the gate electrode pad, and the other end thereof is exposed in the back of the semiconductor substrate. A source electrode connecting conductor is provided in the second cutout section, and one end thereof touches the source electrode pad.

### CROSS-REFERENCE TO RELATED APPLICATIONS

This application is based upon and claims the benefit of priority from the prior Japanese Patent Application No. 2013-045634, filed on Mar. 7, 2013 and the prior Japanese Patent Application No. 2013-109677, filed on May 24, 2013, the entire contents of which are incorporated herein by reference.

### FIELD

An embodiment of the present invention relate to a semiconductor device.

### BACKGROUND

As a conventional semiconductor device, a so-called chip-size-package type semiconductor device in which a semiconductor element, such as a field effect transistor, is covered with a sealing resin, is known, for example. A plurality of solder balls electrically connected to the semiconductor element is provided on a back surface of the semiconductor device. This semiconductor device is mounted on a printed-wiring board via the solder balls. Even if the semiconductor element and the printed-wiring board have curvature, a change in a gap between both is absorbed by an amount of crushing of the solder ball. Therefore, the semiconductor device and the printed-wiring board are connected well.

However, since the semiconductor device is supported by the plurality of the solder balls, a heat generated in the semiconductor device is radiated to a printed-wiring board side via only the plurality of the solder balls. That is, the semiconductor device has a problem that a heat radiation route which conducts the heat generated in the semiconductor device is limited to a route which passes the solder ball, and thereby the heat generated in the semiconductor device is not fully radiated. In addition, the semiconductor device has a problem that the semiconductor device carries out thermal expansion, a crack arises in the solder ball, and a connection between the semiconductor device and the printed-wiring board is disconnected.

When the whole surface of a source electrode back pad which is provided almost all over a back surface is soldered to a printed-wiring board in order to acquire good heat-conducting characteristic and only a gate electrode back pad and a drain electrode back pad are connected to the printed-wiring board by using solder balls, a solder which is in contact with the source electrode back pad and the solder ball make a short circuit. That is, since the source electrode back pad, the gate electrode back pad and the drain electrode back pad exist in the same plane, the solder which is in contact with the source electrode back pad gets in contact with the solder ball by a flow of the solder. If a solder of the same thickness as a thickness of the solder formed on the source electrode back pad is formed on the gate electrode back pad and the drain electrode back pad in order to avoid the short circuit, a change in a gap between the semiconductor device and the printed-wiring board produced by a curvature of the semiconductor device or the printed-wiring board cannot be absorbed by the solder, and good connection will not be obtained.

### BRIEF DESCRIPTION OF THE DRAWINGS

FIG. 1 is a top view schematically showing a semiconductor device concerning an embodiment;

FIG. 2 is a side view of the semiconductor device shown in FIG. 1;

FIG. 3 is other side view of the semiconductor device shown in FIG. 1;

FIG. 4 is a back view of the semiconductor device shown in FIG. 1;

FIG. 5A and FIG. 5B show appearance that the semiconductor device concerning the embodiment is mounted on a printed-wiring board, respectively, and FIG. 5A is a side view corresponding to FIG. 2 and FIG. 5B is a side view corresponding to FIG. 3;

FIG. 6A and FIG. 6B show a semiconductor device concerning a comparative example, respectively, FIG. 6A is a top view corresponding to FIG. 1, and FIG. 6B is a back view corresponding to FIG. 4; and

FIG. 7 shows an appearance that the semiconductor device concerning the comparative example is mounted on a printed-wiring board.

### DETAILED EMBODIMENT

An embodiment provides a semiconductor device which can obtain a good connection with a wiring board, while securing good heat radiation properties.

A semiconductor device according the embodiment includes a plate-like semiconductor substrate, a drain electrode pad, a source electrode pad, a gate electrode pad, a drain electrode connecting conductor, a source electrode connecting conductor, a gate electrode connecting conductor, and a source electrode back pad. The semiconductor substrate has a drain electrode, a source electrode and a gate electrode on a font surface thereof. The semiconductor substrate has a first cutout section in a first side thereof, and a second cutout section and a third cutout section in a second side thereof which is opposite the first side. The drain electrode pad is formed on the front surface of the semiconductor substrate, is connected to the drain electrode, and is exposed in the first side of the semiconductor substrate. The source electrode pad is formed on the front surface of the semiconductor substrate, is connected to the source electrode, and is exposed in the second side of the semiconductor substrate. The gate electrode pad is formed on the front surface of the semiconductor substrate, is connected to the gate electrode, and is exposed in the second side of the semiconductor substrate. The drain electrode connecting conductor is formed in the first cutout section of the semiconductor substrate, one end thereof is connected to the drain electrode pad, and the other end thereof is exposed in the back surface of the semiconductor substrate. The source electrode connecting conductor is formed in the second cutout section of the semiconductor substrate, and one end thereof is connected to the source electrode pad. The gate electrode connecting conductor is formed in the third cutout section of the semiconductor substrate, one end thereof is connected to the gate electrode pad, and the other end thereof is exposed in the back surface of the semiconductor substrate. The source electrode back pad is provided all over the back surface of the semiconductor substrate except for a circumference of the first cutout section and a circumference of the third cutout section, and is connected to the source electrode connecting conductor.

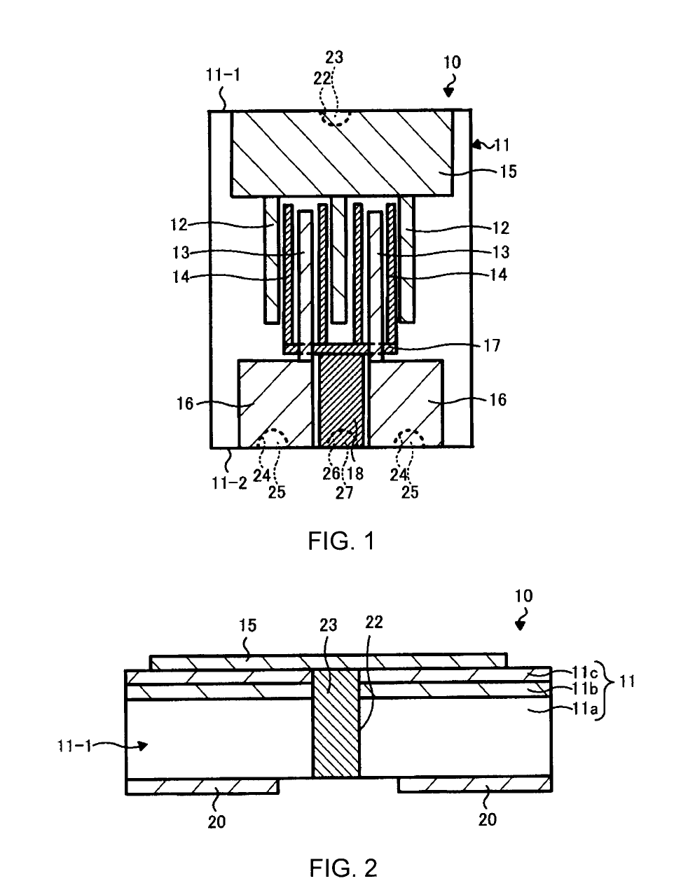

Hereinafter, a semiconductor device concerning the embodiment is explained with reference to the drawings. FIG. 1 is a top view schematically showing a semiconductor device 10 concerning the embodiment. In the semiconductor device 10 shown in FIG. 1, a plurality of finger-like drain electrodes 12, a plurality of finger-like source electrodes 13, and a plurality of finger-like gate electrode 14 are provided on a front surface of a plate-like semiconductor substrate 11. These finger-like electrodes 12, 13 and 14 are provided in parallel mutually so that the gate electrode 14 may be arranged between the drain electrode 12 and the source electrode 13.

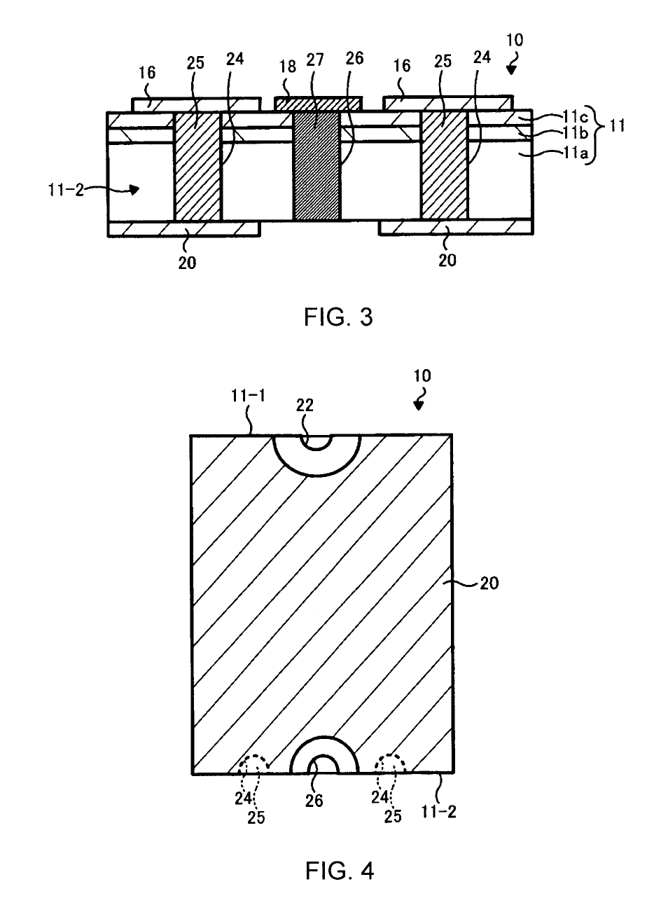

The semiconductor substrate 11 includes a substrate body 11a which is made of a silicon substrate and compound semiconductor layers 11b and 11c which are laminated on the substrate body 11a, for example, as shown in FIG. 2 and FIG. 3. The compound semiconductor layers 11b and 11c include a GaAs layer 11b and an AlGaAs layer 11c, etc., for example. However, in this embodiment, the semiconductor substrate 11 is not restricted to this and may consist of single material.

A square-shaped drain electrode pad 15 which is connected to one ends of the plurality of the finger-like drain electrodes 12 is provided on the front surface of the semiconductor substrate 11. Similarly, a plurality of square-shaped source electrode pads 16 which are connected to one ends of the plurality of the finger-like source electrodes 13 are provided on the front surface of the semiconductor substrate 11. In this embodiment, two source electrode pads 16 are provided. And, a gate bus line 17 which is connected to one ends of the plurality of the finger-like gate electrodes 14 is provided on the front surface of the semiconductor substrate 11, and a square-shaped gate electrode pad 18 is provided on the surface of the semiconductor substrate 11 so as to be connected to the gate bus line 17. The plurality of the source electrode pads 16 are provided in positions opposite to the drain electrode pad 15, and the source electrode pads 16 and the drain electrode pad 15 sandwich the finger-like electrodes 12, 13 and 14. The gate electrode pad 18 is provided among the plurality of the source electrode pads 16.

FIG. 2 is a side view of the semiconductor device 10 shown in FIG. 1, and shows a first side of the semiconductor substrate 11. One side of the drain electrode pad 15 is exposed in the first side 11-1 of the semiconductor substrate 11 which crosses extension lines of the finger-like electrodes 12, 13 and 14. That is, one side of the drain electrode pad 15 and the first side 11-1 of the semiconductor substrate 11 constitute the same plane substantially.

FIG. 3 is another side view of the semiconductor device 10, and shows a second side of the semiconductor substrate 11. As shown in FIG. 3, one side of each of the plurality of the source electrode pads 16 and the gate electrode pad 18 is exposed in the second side 11-2 of the semiconductor substrate 11. That is, one side of each of the plurality of the source electrode pads 16 and the gate electrode pad 18, and the second side 11-2 of the semiconductor substrate 11 constitute the same plane substantially. The second side 11-2 is opposite the first side 11-1.

FIG. 4 is a back view of the semiconductor device 10. The drain electrode connecting conductor 23 and the gate electrode connecting conductor 27 which will be explained later are omitted in FIG. 4.

As shown in FIG. 4, a first cutout section 22 which reaches the back surface from the front surface of the semiconductor substrate 11 is provided in the first side 11-1 of the semiconductor substrate 11. Similarly, a plurality of second cutout sections 24 which reaches the back surface from the front surface of the semiconductor substrate 11 is provided in the second side 11-2 of the semiconductor substrate 11. And, a third cutout section 26 which reaches the back surface from the front surface of the semiconductor substrate 11 is provided among the plurality of the second cutout sections 24 and in the second side 11-2 of the semiconductor substrate 11.

The source electrode back pad 20 which consists of Au, for example, is provided on the back surface of the semiconductor substrate 11. The source electrode back pad 20 is provided all over the back surface of the semiconductor substrate 11 except a circumference of the first cutout section 22 and a circumference of the third cutout section 26. As a result, the source electrode back pad 20 is isolated from the drain electrode connecting conductor 23 (see FIG. 2) provided in the first cutout section 22 and the gate electrode connecting conductor 27 (see FIG. 3) provided in the third cutout section 26. And four sides of this pad 20 are exposed in all the sides of the semiconductor substrate 11 including the first side 11-1 and the second side 11-2.

In addition, as shown in FIG. 1 and FIG. 2, the drain electrode connecting conductor 23 which consists of Au, for example, is provided in the first cutout section 22 of the first side 11-1 of the semiconductor substrate 11. The drain electrode connecting conductor 23 is formed so as to fill an inside of the first cutout section 22. As a result, one end of the drain electrode connecting conductor 23 is connected to the drain electrode pad 15, and the other end thereof is exposed in the back surface of the semiconductor substrate 11.

As shown in FIG. 1 and FIG. 3, the source electrode connecting conductor 25 which consists of Au, for example, is formed in each of the second cutout sections 24 of the second side 11-2 of the semiconductor substrate 11. Each source electrode connecting conductor 25 is formed so as to fill an inside of the second cutout section 24. As a result, one end of the source electrode connecting conductor 25 is connected to the source electrode pad 16, and the other end thereof is connected to the source electrode back pad 20. That is, each source electrode pad 16 on the front surface of the semiconductor substrate 11 is electrically connected to the source electrode back pad 21 by the source electrode connecting conductor 25.

And as shown in FIG. 1 and FIG. 3, the gate electrode connecting conductor 27 which consists of Au, for example, is provided in the third cutout section 26 of the second side 11-2 of the semiconductor substrate 11. The gate electrode connecting conductor 27 is formed so as to fill an inside of the third cutout section 26. As a result, one end of the gate electrode connecting conductor 27 is connected to the gate electrode pad 18, and the other end thereof is exposed in the back surface of the semiconductor substrate 11.

Therefore, the drain electrode connecting conductor 23 and the gate electrode connecting conductor 27 are exposed in the back surface of the semiconductor device 10, and the source electrode back pad 20 is provided all over the back surface of the semiconductor device 10 except these connecting conductors 23 and 27 and their circumferences.

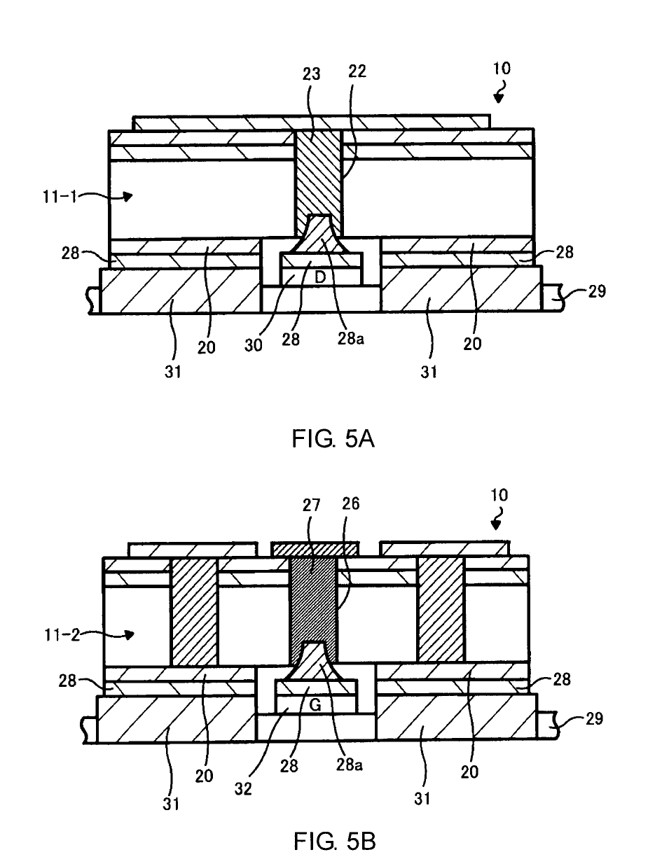

FIG. 5A and FIG. 5B show appearance that the semiconductor device 10 concerning the embodiment is mounted on a printed-wiring board, respectively, and FIG. 5A is a side view corresponding to FIG. 2 and FIG. 5B is a side view corresponding to FIG. 3. As shown in FIG. 5A and FIG. 5B, the source electrode back pad 20 is connected to a grounding case 31 provided in the printed-wiring board 29 via solder 28 provided all over the source electrode back pad 20. The solder 28 and the grounding case 31 serve as a radiating route.

As shown in FIG. 5A, the drain electrode connecting conductor 23 which is provided in the first cutout section 22 of the first side 11-1 of the semiconductor substrate 11 is connected to a drain wiring 30 of the printed-wiring board 29 via a solder meniscus 28a formed by rising part of the solder 28.

Similarly, as shown in FIG. 5B, the gate electrode connecting conductor 27 which is provided in the third cutout section 26 of the second side 11-2 of the semiconductor substrate 11 is connected to a gate wiring 32 of the printed-wiring board 29 via a solder meniscus 28a formed by rising part of the solder 28.

The solder meniscus 28a is formed because the drain electrode connecting conductor 23 and the gate electrode connecting conductor 27 are exposed in the back surface of the semiconductor substrate 11. If a drain electrode back pad and a gate electrode back pad with a larger exposure area than an exposure area of these connecting conductors 23 and 27 are provided in the back surface of the semiconductor substrate 11, the solder meniscus 28a is not formed.

According to the semiconductor device 10 concerning the embodiment described above, the source electrode back pad 20 is formed almost all over the back surface of the semiconductor substrate 11. And the semiconductor device 10 is mounted on the grounding case 31 of the printed-wiring board 29 via the solder 28 provided all over the source electrode back pad 20. Accordingly, since the solder 28 provided almost all over the source electrode back pad 20 serves as a radiating route of a heat which is generated in the semiconductor device 10, the heat which is generated in the semiconductor device 10 can be fully radiated. As a result, the semiconductor device 10 is firmly mounted to the printed-wiring board 29 while a thermal expansion of the semiconductor device 10 is suppressed. Therefore, a disconnection of a connection between the semiconductor device 10 and the printed-wiring board 29 can be suppressed.

In addition, according to the semiconductor device 10 concerning the embodiment, the drain electrode connecting conductor 23 and the gate electrode connecting conductor 27 are exposed in the back surface of the semiconductor substrate 11, respectively. Therefore, the solder meniscus 28a is formed between the drain electrode connecting conductor 23 and the drain wiring 30 of the printed-wiring board 29, and both are connected by the solder meniscus 28a. Similarly, the solder meniscus 28a is formed also between the gate electrode connecting conductor 27 and the gate wiring 32 of the printed-wiring board 29, and both are connected by the solder meniscus 28a. Such solder meniscuses 28a absorb a change in a gap between the semiconductor device 10 and the printed-wiring board 29.

Furthermore, according to the semiconductor device 10 concerning the embodiment, other back pads, such as the drain electrode back pad and the gate electrode back pad, do not exist in the same plane as a plane of the source electrode back pad 20 in the back surface of the semiconductor device 10. Therefore, a short circuit of the solder 28 and the solder meniscus 28a which is caused by a flow of the solder 28 which is in contact with the source electrode back pad 20 is suppressed.

Therefore, according to the semiconductor device 10 concerning the embodiment, the semiconductor device 10 can be connected well to the printed-wiring board 29.

In addition, according to the semiconductor device 10 concerning the embodiment, the cutout sections 22, 24 and 26 are formed in the sides of the semiconductor substrate 11, the drain electrode connecting conductor 23, the source electrode connecting conductor 25, and the gate electrode connecting conductor 27 are provided formed in the cutout sections 22, 24 and 26 of the semiconductor substrate 11. As a result, it is possible to confirm easily a connection state of the drain electrode pad 15 and the drain electrode connecting conductor 23, a connection state of the source electrode pad 16 and the source electrode connecting conductor 25, a connection state of the source electrode back pad 20 and the source electrode connecting conductor 25, and a connection state of the gate electrode pad 18 and the gate electrode connecting conductor 27. In addition, it is possible to observe a state of the solder 28 which connects the drain electrode connecting conductor 23 and the wiring 30 of the printed-wiring board, a state of the solder 28 which connects the gate electrode connecting conductor 27 and the wiring 32 of the printed-wiring board, and a state of the solder 28 which connects the source back electrode 20 and the grounding case 31, and it is also possible to confirm connecting states thereof easily. Accordingly, the semiconductor device 10 concerning the embodiment can improve the reliability of mounting of the semiconductor device 10 to the printed-wiring board 29.

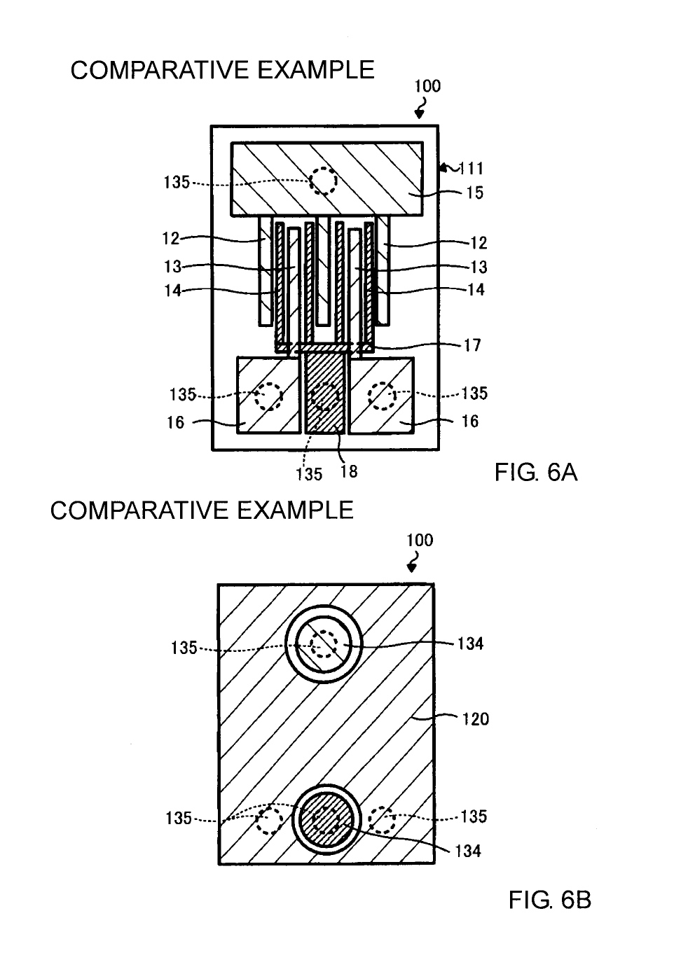

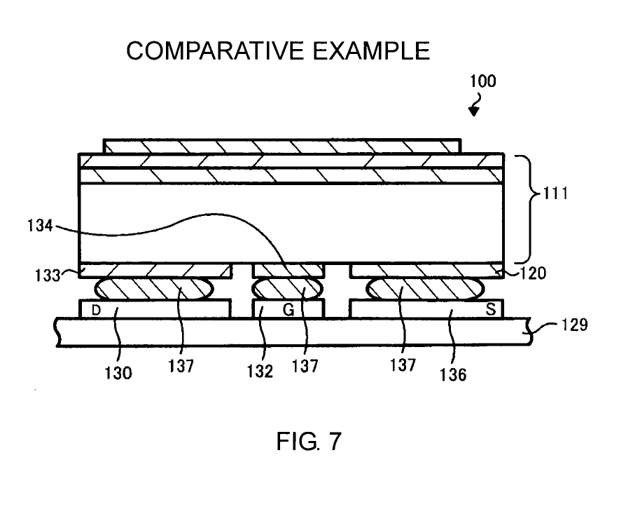

Each of FIG. 6A and FIG. 6B shows a semiconductor device 100 concerning a comparative example, the FIG. 6A is a top view corresponding to FIG. 1, and FIG. 6B is a back view corresponding to FIG. 4. FIG. 7 schematically shows appearance that the semiconductor device 100 concerning the comparative example is mounted on a printed-wiring board. In a below explanation on the semiconductor device 100 concerning the comparative example, the same numeral is given to the same part as a part of the semiconductor device 10 concerning the embodiment, and overlapping explanation is omitted.

As shown in FIG. 6A, in the semiconductor device 100 concerning the comparative example, each of a drain electrode pad 15, a source electrode pad 16, a gate bus line 17, and a gate electrode pad 18 is not exposed in sides of the semiconductor substrate 111. Other composition is the same as that of the semiconductor device 10 concerning the embodiment fundamentally.

As shown in FIG. 6B, a drain electrode back pad 133 and a gate electrode back pad 134 are provided on a back surface of the semiconductor substrate 111. And, the source electrode back pad 120 is provided all over the back surface of the semiconductor substrate 111 except these electrode pads 133 and 134 and circumferences thereof. That is, in the semiconductor device 100 concerning the comparative example, the drain electrode back pad 133 and the gate electrode back pad 134 exist in the same plane as a plane of the source electrode back pad 120.

As shown in FIG. 6A and FIG. 6B, the drain electrode pad 15 and the drain electrode back pad 133 are connected by a penetration electrode 135 (connecting conductor provided in a through-hole) provided in the semiconductor substrate 111. Similarly, the source electrode pad 16 and the source electrode back pad 120 are connected by a penetration electrode 135, and the gate electrode pad 18 and the gate electrode back pad 134 are connected by a penetration electrode 135.

In the semiconductor device 100 concerning the comparative example like this, as shown in FIG. 7, for example, the drain electrode back pad 133, the source electrode back pad 120 and the gate electrode back pad 134 which are provided on the back surface of the semiconductor substrate 111, are connected to a drain wiring 130, a source wiring 136, and a gate wiring 132 of the printed-wiring board 129, via solder balls 137, respectively. Thus, the semiconductor device 100 concerning the comparative example is mounted on the printed-wiring board 129.

The semiconductor device 100 concerning the comparative example explained above is supported and mounted only by a plurality of the solder balls 137. For this reason, a heat generated in the semiconductor device 100 is radiated to a printed-wiring board 129 side via only the plurality of the solder balls 137. That is, a radiating route of the heat generated in the semiconductor device 100 of the comparative example is restricted to a course which passes each solder ball 137, and the heat generated in the semiconductor device 100 is not adequately radiated.

Although illustration is omitted, if the whole surface of each electrode back pads 133, 134 and 120 is soldered in order to obtain high heat radiation properties, a change in a gap between the semiconductor device 100 and the printed-wiring board 129 can not be absorbed. In addition to this, since the drain electrode back pad 133 and the gate electrode back pad 134 exist in the same plane as a plane of the source electrode back pad 120, a solder which is in contact with the source electrode back pad 120, and a solder which is in contact with the drain electrode back pad 133 and the gate electrode back pad 134 will make a short-circuit. Therefore, in the semiconductor device 100 concerning the comparative example, if the solder is used in replace of the solder ball 137, it will become difficult to connect the semiconductor device 100 well to the printed-wiring board 129.

Furthermore, in the semiconductor device 100 concerning the comparative example, the electrode pads 15, 16 and 18 are connected to the electrode back pads 133, 120 and 134 by the penetration electrodes 135, respectively. Therefore, it is, particularly, difficult to confirm visually a connection state of the drain electrode pad 15 and the drain electrode back pad 133 and a connection state of the gate electrode pad 18 and the gate electrode back pad 134, from exterior of the semiconductor device 100. Accordingly, the reliability of mounting of the semiconductor device 100 to the printed-wiring board 129 is bad.

While the embodiment has been described, the embodiment has been presented by way of example only, and is not intended to limit the scope of the inventions. Indeed, the novel embodiment described herein may be embodied in a variety of other forms; furthermore, various omissions, substitutions and changes in the form of the embodiment described herein may be made without departing from the spirit of the inventions. The accompanying claims and their equivalents are intended to cover such forms or modifications as would fall within the scope and spirit of the inventions.

What is claimed is:

1. A semiconductor device, comprising:
a plate-like semiconductor substrate which has a drain electrode, a source electrode and a gate electrode on a front surface, which has a first cutout section in a first side and which has a second cutout section and a third cutout section in a second side which is opposite the first side;
a drain electrode pad which is provided on the front surface of the semiconductor substrate and is connected to the drain electrode, and of which one side is exposed in the first side of the semiconductor substrate;
a source electrode pad which is provide on the front surface of the semiconductor substrate and is connected to the source electrode, and of which one side is exposed in the second side of the semiconductor substrate;
a gate electrode pad which is provided on the front surface of the semiconductor substrate and is connected to the gate electrode, and of which one side is exposed in the second side of the semiconductor substrate;
a drain electrode connecting conductor which is provided in the first cutout section of the semiconductor substrate, of which one end is connected to the drain electrode pad, and of which the other end is exposed in a back surface of the semiconductor substrate;
a source electrode connecting conductor which is provided in the second cutout section of the semiconductor substrate, and of which end of is connected to the source electrode pad;
a gate electrode connecting conductor which is provided in the third cutout section of the semiconductor substrate, of which one end is connected to the gate electrode pad, and of which the other end is exposed in the back of the semiconductor substrate; and
a source electrode back pad which is provided all over the back surface of the semiconductor substrate except for a circumference of the first cutout section and a circumference of the third cutout section, and which is connected to the source electrode connecting conductor.

2. The semiconductor device according to claim 1, wherein
the semiconductor substrate includes a substrate body and a plurality of compound semiconductor layers laminated on the surface of the substrate body, and
the drain electrode, the source electrode, the gate electrode, the drain electrode pad, the source electrode pad, and the gate electrode pad are provided on the plurality of the compound semiconductor layers.

3. The semiconductor device according to claim 2, wherein the plurality of the compound semiconductor layers are an AlGaAs layer and a GaAs layer.

4. A semiconductor device, comprising:
a plate-like semiconductor substrate which has a drain electrode, a source electrode and a gate electrode on a front surface, which has a first cutout section in a first side and which has a second cutout section and a third cutout section in a second side which is opposite the first side;
a drain electrode connecting conductor which is provided in the first cutout section of the semiconductor substrate, of which one end is electrically connected to the drain electrode, and of which the other end is exposed in a back surface of the semiconductor substrate;
a source electrode connecting conductor which is provided in the second cutout section of the semiconductor substrate, and of which end of is electrically connected to the source electrode;
a gate electrode connecting conductor which is provided in the third cutout section of the semiconductor substrate, of which one end is electrically connected to the gate electrode, and of which the other end is exposed in the back of the semiconductor substrate; and
a source electrode back pad which is provided all over the back surface of the semiconductor substrate except for a circumference of the first cutout section and a circumference of the third cutout section, and which is connected to the source electrode connecting conductor.
